(19) United States
(12) Patent Application Publication
(10) Pub. No.: US 2025/0230541 A1
(43) Pub. Date: Jul. 17, 2025

(54) Gapfill Process Using Pulsed High-Frequency Radio-Frequency (HFRF) Plasma

(71) Applicant: Applied Materials, Inc., Santa Clara, CA (US)

(72) Inventors: Rui Cheng, Santa Clara, CA (US); Guoqing Li, Santa Clara, CA (US); Qinghua Zhao, Santa Clara, CA (US)

(73) Assignee: Applied Materials, Inc., Santa Clara, CA (US)

(21) Appl. No.: 19/057,197

(22) Filed: Feb. 19, 2025

Related U.S. Application Data
(63) Continuation of application No. 18/216,138, filed on Jun. 29, 2023.
Application No. 18/216,138 is a continuation-in-part of application No. 17/157,307, filed on Jan. 25, 2021, now abandoned.

(51) Int. Cl. C23C 16/04; C23C 16/32; H01J 37/32; H01L 21/02

(52) U.S. Cl. CPC C23C 16/045; C23C 16/32; H01J 37/32082; H01L 21/02274; H01L 21/0228; H01J 2237/3321; H01J 2237/334

(57) ABSTRACT

Methods for forming a metal carbide liner in features formed in a substrate surface are described. Each of the features extends a distance into the substrate from the substrate surface and have a bottom and at least one sidewall. The methods include depositing a metal carbide liner in the feature of the substrate surface with a plurality of high-frequency ratio-frequency (HFRF) pulses. Semiconductor devices with the metal carbide liner and methods for filling gaps using the metal carbide liner are also described.

### CROSS-REFERENCE TO RELATED APPLICATIONS

This application is a continuation of U.S. application Ser. No. 18/216,138, filed Jun. 29, 2023, which is a continuation-in-part of U.S. patent application Ser. No. 17/157,307, filed Jan. 25, 2021, the entire disclosures of which are hereby incorporated by reference herein.

### TECHNICAL FIELD

The present disclosure relates generally to methods for gapfill. In particular, the disclosure relates to processes to fill a gap using a pulsed high-frequency radio-frequency (HFRF) plasma.

### BACKGROUND

In microelectronics device fabrication there is a need to fill narrow trenches having aspect ratios (AR) greater than 10:1 with no voiding for many applications. One application is for shallow trench isolation (STI). For this application, the film needs to be of high quality throughout the trench (having, for example, a wet etch rate ratio less than two) with very low leakage. One method that has had past success is flowable CVD. In this method, oligomers are carefully formed in the gas phase which condense on the surface and then “flow” into the trenches. The as-deposited film is of very poor quality and requires processing steps such as steam anneals and UV-cures.

As the dimensions of the structures decrease and the aspect ratios increase post curing methods of the as deposited flowable films become difficult. Resulting in films with varying composition throughout the filled trench.

Amorphous silicon has been widely used in semiconductor fabrication processes as a sacrificial layer since it can provide good etch selectivity with respect to other films (e.g., silicon oxide, amorphous carbon, etc.). With decreasing critical dimensions (CD) in semiconductor fabrication, filling high aspect ratio gaps becomes increasingly sensitive for advanced wafer fabrication. Current metal replacement gate processes involve a furnace poly-silicon or amorphous silicon dummy gate. A seam forms in the middle of the Si dummy gate due to the nature of process. This seam may open during the post process and cause structure failure.

Conventional plasma-enhanced chemical vapor deposition (PECVD) of amorphous silicon (a-Si) forms a “mushroom shape” film on top of the narrow trenches. This is due to the inability of the plasma to penetrate into the deep trenches. The results is the pinching-off of the narrow trench from the top; forming a void or seam at the bottom of the trench.

Conventional thermal CVD/furnace processes can grow a-Si via thermal decomposition of a silicon precursor (e.g., silane, disilane). However, due to the inadequate precursor supply or presence of decomposition byproduct, the deposition rate is higher on top of trenches compared with it at the bottom. A narrow seam or void can be observed in the trench.

Additionally, many semiconductor device applications incorporate a conformal liner. As the device dimensions shrink, the conventional plasma-enhanced chemical vapor deposition of metal carbides (e.g., tungsten carbide) form mushroom-shaped films on the tops of narrow trenches with very thin films at the sidewalls. This shape film does not work as a conformal liner due to the inability of the plasma to penetrate into the deep trenches.

Accordingly, there is a need for methods for forming metal carbide conformal liners in semiconductor devices.

### SUMMARY

One or more embodiments of the disclosure are directed to a methods of gap filling. A substrate surface of a substrate is exposed to a deposition process comprising a pulsed high-frequency radio-frequency (HFRF) plasma having a plurality of HFRF pulses to deposit a liner. The substrate surface has a plurality of features formed therein. Each of the plurality of features extends a distance into the substrate from the substrate surface and has a bottom and at least one sidewall. The liner comprises a metal carbide.

Additional embodiments of the disclosure are directed to methods of using HFRF to form a liner. A metal carbide liner is formed on sidewalls of a plurality of features formed in a substrate surface. Each feature extends a distance into a substrate from the substrate surface and has at least one sidewall. Forming the liner comprises exposing the substrate to a chemical vapor deposition process with a plurality of liner HFRF pulses.

Further embodiments of the disclosure are directed to methods of forming a liner in a semiconductor device. A metal carbide liner is formed on sidewalls of a plurality of features formed in a substrate surface. Each feature extends a distance into the substrate from the substrate surface and has at least one sidewall. Forming the metal carbide liner comprises exposing the substrate to a chemical vapor deposition process using one or more of a tungsten-containing precursor, a molybdenum-containing precursor or a nickel-containing precursor, and a plurality of liner HFRF pulses to form a metal carbide liner with a tensile stress.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional view of a substrate feature in accordance with one or more embodiment of the disclosure; and

FIG. 2 shows a process flow in accordance with one or more embodiments of the disclosure.

FIGS. 3A through 3D show cross-sectional schematic representations of a gapfill process in accordance with one or more embodiments of the disclosure.

FIGS. 4A through 4B show cross-sectional schematic representations of a metal carbide liner formation process in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure provide low temperature silicon gapfill processes. By first depositing and then etching a silicon film around some trench structures produced considerably thicker amounts of amorphous silicon (a-Si) films at the bottom of the trenches compared to the sidewalls or the top of the trench. Some embodiments provide methods that cycle deposition and etching to form a seamfree silicon gapfill.

Embodiments of the disclosure provide methods of depositing a film (e.g., amorphous silicon) in high aspect ratio (AR) structures with small dimensions. Some embodiments advantageously provide methods involving cyclic deposition-etch-treatment processes that can be performed in a cluster tool environment. Some embodiments advantageously provide seam-free doped or alloyed high quality amorphous silicon films to fill up high AR trenches with small dimensions.

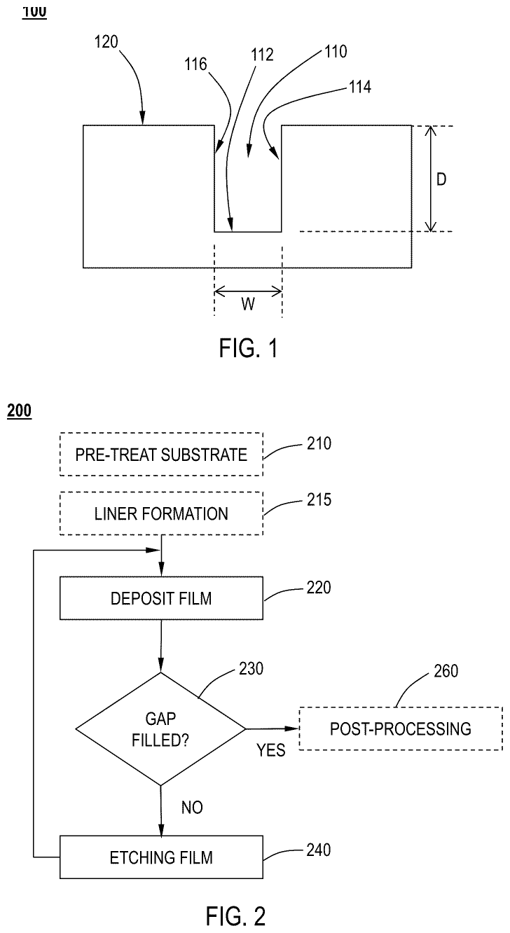

FIG. 1 shows a partial cross-sectional view of a substrate 100 with a feature 110. The Figures show substrates having a single feature for illustrative purposes; however, those skilled in the art will understand that there can be more than one feature. The shape of the feature 110 can be any suitable shape including, but not limited to, trenches and cylindrical vias. As used in this regard, the term “feature” means any intentional surface irregularity. Suitable examples of features include, but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

The substrate 100 has a substrate surface 120. The at least one feature 110 forms an opening in the substrate surface 120. The feature 110 extends from the substrate surface 120 to a depth D to a bottom surface 112. The feature 110 has a first sidewall 114 and a second sidewall 116 that define a width W of the feature 110. The open area formed by the sidewalls and bottom are also referred to as a gap.

During gap filling processes, it is common for a seam to form in the fill material. The size and width of the seam may affect the overall operability of the gapfill component. The size and width of the seam can also be affected by the process conditions and the material being deposited. Accordingly, one or more embodiments advantageously provide methods for seam-free (or void-free) gap filling. Some embodiments of the method advantageously disclose cyclic deposition-treatment-etch process for the gap filling. In some embodiments, the gap filling is seam-free.

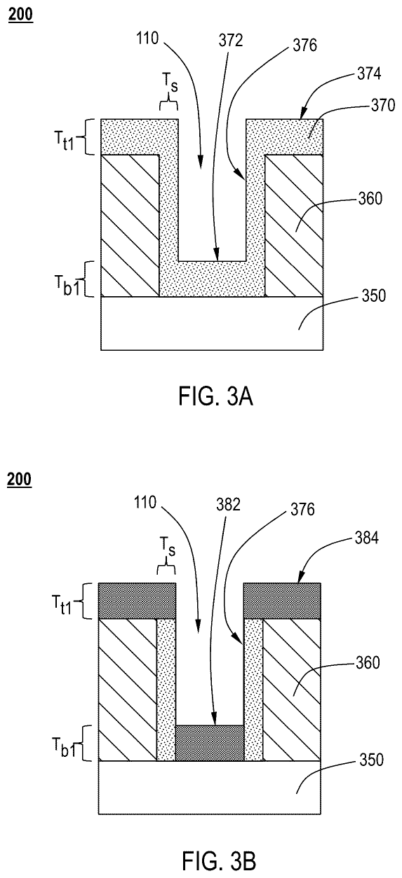

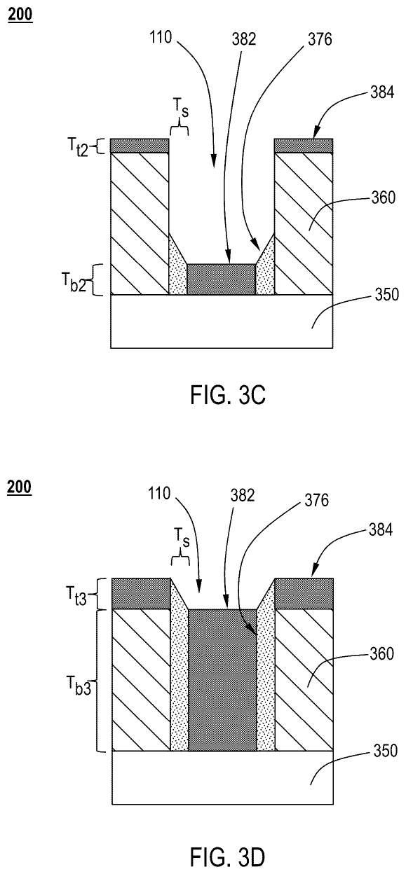

FIGS. 2 and 3A through 3D show an exemplary gap filling method 200 in accordance with one or more embodiments of the disclosure. In the embodiment illustrated in FIG. 2, the method 200 is performed on the substrate 100 having at least one feature 110. In some embodiments, the feature 110 has an aspect ratio greater than or equal to 5:1, 10:1, 15:1, 20:1, 25:1, 30:1, 35:1 or 40:1. In some embodiments, the method 200 comprises depositing a film 220 and etching the film 240. In some embodiments, the film deposition 220 and/or the film etching 240 is performed in one or more processing chamber in a cluster tool environment. In some embodiments, the film deposition 220 and/or the film etching 240 comprises a plurality of high-frequency radio-frequency (HFRF) pulses. In one or more embodiments, the plasma comprises a pulsed HFRF plasma. In some embodiments, the pulsed HFRF plasma comprises a plurality of HFRF pulses. In some embodiments, the pulsed HFRF plasma deposits a non-conformal film.

Some embodiments advantageously provide methods that use plasma to etch materials (e.g., Si) faster on the sidewalls of the features than the bottom of the features. Some embodiments advantageously use the different etch rates on different surfaces and different locations to create bottom-up growth by cycling the deposition-etch process.

In the embodiment illustrated in FIG. 3A, the substrate 100 has a feature 110 formed thereon and two different surfaces: a first surface 350 and a second surface 360. The first surface 350 and the second surface 360 can be different materials. For example, one of the surfaces may be a metal and the other a dielectric. In some embodiments, the first surface 350 and the second surface 360 have the same chemical composition but different physical properties (e.g., crystallinity). In describing the methods below, reference to the substrate 100 means the first surface 350 and second surface 360 or a single surface in which the features 110 is formed.

In the embodiment illustrated in FIG. 3A, the feature 110 is formed by the first surface 350 and the second surface 360. The feature 110 illustrated is a trench in which the first surface 350 forms the bottom of the feature and the second surface 360 form the sidewalls and top.

The method 200 of some embodiments includes an optional substrate pre-treatment 210. In some embodiments, substrates are exposed to one or more process condition to pre-treat or prepare the substrate surface for deposition. For example, pre-treatment in some embodiments densifies the substrate surface or changes the surface terminations. In some embodiments, the optional pre-treatment 210 comprises one or more of polishing, etching, reducing, oxidizing, hydroxylating, annealing, UV curing, e-beam curing, plasma treatment and/or baking the substrate surface. In some embodiments, the plasma treatment comprises NH₃ plasma treatment.

In some embodiments, a liner is formed in the feature 110 in liner formation process 215. The liner formation process 215 is an optional process which can be included in the method 200 or can be part of a separate method.

At deposition process 220, a film 370 is deposited on the substrate 100. In one or more embodiments, depositing the film 370 comprises a plasma-enhanced chemical vapor deposition (PECVD) process or a plasma-enhanced atomic layer deposition (PEALD) process. In some embodiments, the deposition process 220 comprises a PECVD process. In some embodiments, the deposition process 220 comprises a PEALD process. In some embodiments, the PECVD comprises a gapfill pulsed high-frequency radio-frequency (HFRF) plasma. In some embodiments, the gapfill pulsed HFRF plasma comprises a plurality of gapfill HFRF pulses. The gapfill pulsed HFRF plasma may also be referred to as a “first” HFRF plasma. The use of ordinals such as “first”, “second”, etc., are used to identify different processes or components and are not intended to imply a specific order of operation or use.

As used herein, a high-frequency radio-frequency plasma comprises high-frequency on/off pulses of power. When on, the power is delivered at radio-frequency. The pulse frequency and radio frequency refer to different aspects of the power used to generate a plasma that can be independently controlled.

The film 370 can be any suitable film that can be selectively deposited on the first surface 350 relative to the second surface 360. In some embodiments, the film 370 comprises silicon. In some embodiments, the film 370 consists essentially of silicon. As used in this manner, the term “consists essentially of” means that the film is greater than or equal to about 90%, 93%, 95%, 98% or 99% silicon (or the stated species) on an atomic basis. In some embodiments, the film 370 comprises amorphous silicon. In some embodiments, the film 370 comprises substantially only amorphous silicon. As used in this manner, the term “substantially only amorphous silicon” means that the film 370 is greater than or equal to about 90%, 93%, 95%, 98% or 99% amorphous silicon.

FIG. 3A illustrates the film 370 formed on the substrate surface (top 374), sidewalls 376 and bottom 372 of the feature 110. The film 370 deposited on the substrate will have a film thickness Tₛ at the sidewall of the feature, a film thickness Tₜ at the top of the feature (i.e., on the surface of the substrate) and a film thickness T_{b} at the bottom of the feature 110.

In some embodiments, the film 370 forms non-conformally on the at least one feature. As used herein, the term “non-conformal”, or “non-conformally”, refers to a layer that adheres to and non-uniformly covers exposed surfaces with a thickness variation of greater than 10% relative to the average thickness of the film. For example, a film having an average thickness of 100 Å would have greater than 10 Å variations in thickness. This thickness variation includes edges, corners, sides, and the bottom of recesses. In some embodiments, the variation is greater than or equal to 10%, 15%, 20%, 25%, 30%, 35%, 40%, 45%, 50%, 55%, 60%, 65%, 70%, 75%, 80%, 85% or 90%. In some embodiments, a film deposited on sidewalls of a trench is thinner than the thickness of the film deposited on the bottom of the trench or surface in which the trench is formed. In some embodiments, the average thickness of the deposited film on the sidewalls is less than or equal to 90%, 80%, 70%, 60%, 50%, 40%, 30% or 20% of the average thickness on the bottom and/or top of the trench.

In some embodiments, the film 370 is deposited to the average thickness in the range of from 1 nm to 100 nm, from 1 nm to 80 nm, from 1 nm to 50 nm, from 10 nm to 100 nm, from 10 nm to 80 nm, from 10 nm to 50 nm, from 20 nm to 100 nm, from 20nm to 80 nm or from 20 nm to 50 nm before stopping deposition. In some embodiments, the film 370 is deposited to the average thickness in the range of from 5 nm to 100 nm, from 5 nm to 80 nm, from 5 nm to 40 nm, from 5 nm to 30 nm or from 10 nm to 30 nm.

The process parameters used for depositing the film 370 can affect the film thickness at the sidewall of the feature, top of the feature and/or bottom of the feature. For example, the particular precursors and/or reactive species, plasma conditions, temperature, etc. In some embodiments, the thickness Tₜ at the top of the feature is greater than the thickness Tₛ at the sidewall of the feature. In some embodiments, the thickness T_{b} at the bottom of the feature is greater than the thickness Tₛ at the sidewall of the feature. In some embodiments, the thickness Tₜ at the top of the feature is greater than the thickness T_{b} at the bottom of the feature. In some embodiments, the thickness T_{b} at the bottom of the feature is greater than the thickness Tₜ at the top of the feature.

During the film deposition 220 process, the substrate is exposed to one or more process gases and/or conditions that form the film 370. In some embodiments, the process gas flows into a processing region of a process chamber and a pulsed HFRF plasma is formed from the process gas to deposit the film 370. The process gas of some embodiments includes a silicon precursor and a carrier gas, and the carrier gas is ignited into a plasma by HFRF power.

In one or more embodiments, the gapfill pulsed HFRF plasma is a conductively-coupled plasma (CCP) or inductively coupled plasma (ICP). In some embodiments, the gapfill pulsed HFRF plasma is a direct plasma or a remote plasma. In some embodiments, each of the plurality of gapfill HFRF pulses are independently generated at a gapfill power in a range of from 0 W to 500 W, from 50 W to 500 W, from 50 W to 400 W, from 50 W to 300 W, from 50 W to 200 W, from 50 W to 100 W, from 100 W to 500 W, from 100 W to 400 W, from 100 W to 300 W, from 100 W to 200 W, from 200 W to 500 W, from 200 W to 400 W or from 200 W to 300 W. In some embodiments, the minimum gapfill plasma power is greater than 0 W. In some embodiments, all of the gapfill pulses have the same power. In some embodiments, the individual pulse powers in the gapfill HFRF plasma vary.

In one or more embodiments, the plurality of gapfill HFRF plasma pulses have a gapfill duty cycle in a range of from 1% to 50%, from 1% to 45%, from 1% to 40%, from 1% to 35%, from 1% to 30%, from 1% to 25%, from 1% to 20%, form 1% to 15%, from 1% to 10%, from 5% to 50%, from 5% to 45%, from 5% to 40%, from 5% to 35%, from 5% to 30%, from 5% to 25%, from 5% to 20%, form 5% to 15%, from 5% to 10%, from 10% to 50%, from 10% to 45%, from 10% to 40%, from 10% to 35%, from 10% to 30%, from 10% to 25%, from 10% to 20% or form 10% to 15%. In some embodiments, each of the plasma pulses during the gapfill deposition process have the same duty cycle. In some embodiments, the duty cycle changes during the gapfill deposition process.

In one or more embodiments, each of the plurality of gapfill HFRF plasma pulse independently has a pulse width in a range of from 5 msec to 50 μsec, from 4msec to 50 μsec, from 3 msec to 50 μsec, from 2 msec to 50 μsec, from 1 msec to 50μsec, from 800 μsec to 50 μsec, from 500 μsec to 50 μsec, from 200 μsec to 50 μsec, from 5 msec to 100 μsec, from 4 msec to 100 μsec, from 3 msec to 100 μsec, from 2 msec to 100 μsec, from 1 msec to 100 μsec, from 800 μsec to 100 μsec, from 500 μsec to 100 μsec and from 200 μsec to 100 μsec. In some embodiments, each of the pulse widths are the same during the deposition process. In some embodiments, the pulse widths vary during the deposition process.

In one or more embodiments, each of the plurality of gapfill HFRF plasma pulses independently has a gapfill pulse frequency in a range of from 0.1 kHz to 20 KHz, from 0.1 kHz to 15 KHz, from 0.1 KHz to 10 kHz, from 0.1 kHz to 5 kHz, 0.5 kHz to 20 KHz, from 0.5 kHz to 15 kHz, from 0.5 kHz to 10 KHz, from 0.5 kHz to 5 kHz, 1 kHz to 20 kHz, from 1 kHz to 15 kHz, from 1 kHz to 10 KHz, from 1 kHz to 5 kHz, 2 kHz to 20 kHz, from 2 kHz to 15 kHz, from 2 kHz to 10 kHz or from 2 kHz to 5 kHz. In some embodiments, the pulse frequency remains the same during the deposition process. In some embodiments, the pulse frequency varies during the deposition process.

In one or more embodiments, the plurality of gapfill HFRF pulses have a gapfill radio frequency in a range of from 5 MHz to 20 MHZ, from 5 MHz to 15 MHZ, from 5 MHz to 10 MHz, from 10 MHz to 20 MHz or from 10 MHz to 15 MHz. In one or more embodiments, the plurality of gapfill HFRF pulses have the first radio frequency of 13.56 MHz. In some embodiments, the radio frequency of the pulses are the same during the deposition process. In some embodiments, the radio frequencies of the pulses vary during the deposition process. In one or more embodiments, each of the plurality of gapfill HFRF pulses independently has a first radio frequency in a range of from 5 MHz to 20 MHz, from 5 MHz to 15 MHZ, from 5 MHz to 10 MHz, from 10 MHz to 20 MHz or from 10 MHz to 15 MHz. In one or more embodiments, each of the plurality of gapfill HFRF pulses independently has the first radio frequency of 13.56 MHz.

In one or more embodiments, each of the plurality of gapfill HFRF pulses have a gapfill duty cycle in a range of from 1% to 50%, from 1% to 45%, from 1% to 40%, from 1% to 35%, from 1% to 30%, from 1% to 25%, from 1% to 20%, form 1% to 15%, from 1% to 10%, from 5% to 50%, from 5% to 45%, from 5% to 40%, from 5% to 35%, from 5% to 30%, from 5% to 25%, from 5% to 20%, form 5% to 15%, from 5% to 10%, from 10% to 50%, from 10% to 45%, from 10% to 40%, from 10% to 35%, from 10% to 30%, from 10% to 25%, from 10% to 20% or form 10% to 15%. In some embodiments, the duty cycle of the pulses is the same during the deposition process. In some embodiments, the duty cycles of the pulses vary during the deposition process.

The deposition process 220 can occur at any suitable substrate temperature. In some embodiments, during the deposition process 220, the substrate is maintained at a gapfill temperature in the range of 15° C. to 250° C., from 15° C. to 225° C., from 15° C. to 200° C., from 15° C. to 175° C., from 15° C. to 150° C., from 15° C. to 125° C., from 15° C. to 100° C., from 25° C. to 250° C., from 25° C. to 225° C., from 25° C. to 200° C., from 25° C. to 175° C., from 25° C. to 150° C., from 25° C. to 125° C., from 25° C. to 100° C., from 50° C. to 250° C., from 50° C. to 225° C., from 50° C. to 200° C., from 50° C. to 175° C., from 50° C. to 150° C., from 50° C. to 125° C., from 50° C. to 100° C., from 75° C. to 250° C., from 75° C. to 225° C., from 75° C. to 200° C., from 75° C. to 175° C., from 75° C. to 150° C., from 75° C. to 125° C. or from 75° C. to 100° C.

In one or more embodiments, the film deposition process 220 comprises flowing one or more of a first carrier gas, a precursor or a first reactant onto the substrate surface. In some embodiments, the carrier gas includes but is not limited to argon (Ar), helium He, H₂ or N₂. In some embodiments, the carrier gas comprises or consists essentially of helium (He). In some embodiments, the carrier gas comprises argon (Ar). In one or more embodiments, the precursors include, but are not limited to, silane, disilane, dichlorosilane (DCS), trisilane, or tetrasilane. In some embodiments, the precursor gas comprises silane (SiH₄). In some embodiments, the precursor gas comprises or consists essentially of disilane (Si₂H₆). In some embodiments, the precursor gas is heated in a hot can to increase the vapor pressure and be delivered to the chamber using the carrier gas. In some embodiments, the first reactant gas comprises H₂.

In one or more embodiments, each of the gapfill carrier gas, the precursor gas or the gapfill reactant gas are flown onto the substrate surface independently at a dose in a range of from 40 sccm to 10000 sccm, from 40 sccm to 5000 sccm, from 40 sccm to 2000 sccm, from 40 sccm to 1000 sccm, from 40 sccm to 500 sccm, from 40 sccm to 100 sccm, from 100 sccm to 10000 sccm, from 100 sccm to 5000 sccm, from 100 sccm to 2000 sccm, from 100 sccm to 1000 sccm, from 100 sccm to 500 sccm, from 250 sccm to 10000 sccm, from 250 sccm to 5000 sccm, from 250 sccm to 2000 sccm, from 250 sccm to 1000 sccm, from 250 sccm to 500 sccm, from 500 sccm to 10000 sccm, from 500 sccm to 5000 sccm, from 500 sccm to 2000 sccm or from 500 sccm to 1000 sccm.

In some embodiments, as shown in FIG. 3A, the film 370 deposited during deposition process 220 is a continuous film. As used herein, the term “continuous” refers to a layer that covers an entire exposed surface without gaps or bare spots that reveal material underlying the deposited layer. A continuous film may have gaps or bare spots with a surface area less than about 1% of the total surface area of the film.

After the deposition process 220, the method 200 reaches decision point 230. At decision point 230, the fill condition of the feature is evaluated. If the feature 110 or gap has been completely filled, the method 200 can be stopped and the substrate can be subjected to an optional post-processing 260. If the feature or gap has not been filled, the method 200 moves to an etching treatment 240.

In one or more embodiments, after the deposition process 220 but before the etching treatment 240, the substrate 100 subject to a purging treatment and/or vacuum treatment. In some embodiments, a purge gas, such as argon, is introduced into the processing chamber to purge the reaction zone or otherwise remove any residual reactive compound or by-products from the reaction zone between the deposition process 220 and the etching treatment 240. In some embodiments, the purge gas is continuously flown into the processing chamber throughout the method 200. In some embodiments, a negative pressure is applied into the processing chamber to remove any residual reactive compound or by-products from the reaction zone between the deposition process 220 and the etching treatment 240. In some embodiments, the negative pressure is continuously applied into the processing chamber throughout the method 200. In some embodiments, the purging treatment and/or vacuum treatment is applied before the post-processing treatment 260.

In one or more embodiments, the etching treatment 240 etches the non-conformal film. In some embodiments, the etching treatment 240 etches a greater thickness Tₛ of the film 370 on the sidewall of the features 110 than a thickness T_{b} from the bottom of the features 110. In one or more embodiments, the etching treatment etches a greater thickness Tₛ of the film 370 on the sidewall of the features 110 than a thickness Tt from the top of the features 110.

Without being bound by any particular theory of operation, it is believed that the directional plasma treatment preferentially modifies the top film 374 and bottom film 372 with respect to the sidewall film 376. The modified film seems to be more etch resistant. This leads to higher sidewall etch rate later on. FIG. 3B illustrates the feature 110 that has been subject to the film etching causing modification of the top film 384 and the bottom film 382 according to one or more embodiments of the disclosure.

FIG. 3C illustrated etched film according to one or more embodiments of the disclosure. Etching the film 370 removes substantially all of the sidewall film 376 from the feature 110 and leaving some of the top film 384 and the bottom film 382. In some embodiments, removing substantially all of the sidewall film 376 means that at least about 95%, 98% or 99% of the surface area of the side walls has been etched. In some embodiments, removing substantially all of the sidewall film 376 comprises a nucleation delay for a subsequent deposition process 220.

In one or more embodiments, the etching treatment 240 comprises exposing the substrate surface to one or more of an etch carrier gas or an etch reactant gas. In some embodiments, the second carrier gas comprises one or more of argon (Ar), helium (He) or nitrogen (N₂). In some embodiments, the second reactant gas comprises one or more of Cl₂, H₂, NF₃ or HCl. In some embodiments, the second reactant gas comprises or consists essentially of H₂. In some embodiments, each of the second carrier gas or the second reactant gas are flown onto the substrate surface independently at a flow rate in a range of from 40 sccm to 10000 sccm, from 40 sccm to 5000 sccm, from 40 sccm to 2000 sccm, from 40 sccm to 1000 sccm, from 40 sccm to 500 sccm, from 40 sccm to 100 sccm, from 100 sccm to 10000 sccm, from 100 sccm to 5000 sccm, from 100 sccm to 2000 sccm, from 100 sccm to 1000 sccm, from 100 sccm to 500 sccm, from 250 sccm to 10000 sccm, from 250 sccm to 5000 sccm, from 250 sccm to 2000 sccm, from 250 sccm to 1000 sccm, from 250 sccm to 500 sccm, from 500 sccm to 10000 sccm, from 500 sccm to 5000 sccm, from 500 sccm to 2000 sccm or from 500 sccm to 1000 sccm.

In one or more embodiments, the etching treatment 240 comprises maintaining the substrate 100 a temperature in a range of from 15° C. to 250° C., from 15° C. to 225° C., from 15° C. to 200° C., from 15° C. to 175° C., from 15° C. to 150° C., from 15° C. to 125° C., from 15° C. to 100° C., from 25° C. to 250° C., from 25° C. to 225° C., from 25° C. to 200° C., from 25° C. to 175° C., from 25° C. to 150° C., from 25° C. to 125° C., from 25° C. to 100° C., from 50° C. to 250° C., from 50° C. to 225° C., from 50° C. to 200° C., from 50° C. to 175° C., from 50° C. to 150° C., from 50° C. to 125° C., from 50° C. to 100° C., from 75° C. to 250° C., from 75° C. to 225° C., from 75° C. to 200° C., from 75° C. to 175° C., from 75° C. to 150° C., from 75° C. to 125° C. or from 75° C. to 100° C. In some embodiments, the substrate is maintained at the same temperature during the deposition process 220 and the etching treatment 240. In some embodiments, the substrate is maintained at a different (ΔT>10° C.) temperature during the deposition process 220 and the etching treatment 240.

In one or more embodiments, the etching treatment 240 comprises maintaining the substrate 100 a pressure in a range of from 0.1 Torr to 12 Torr, from 0.5 Torr to 12 Torr, from 1 Torr to 12 Torr, from 2 Torr to 12 Torr, from 3 Torr to 12 Torr, from 4 Torr to 12 Torr, from 0.1 Torr to 10 Torr, from 0.5 Torr to 10 Torr, from 1 Torr to 10 Torr, from 2 Torr to 10 Torr, from 3 Torr to 10 Torr, from 4 Torr to 10 Torr, from 0.1 Torr to 8 Torr, from 0.5 Torr to 8 Torr, from 1 Torr to 8 Torr, from 2 Torr to 8 Torr, from 3 Torr to 8 Torr, from 4 Torr to 8 Torr, from 0.1 Torr to 5 Torr, from 0.5 Torr to 5 Torr, from 1 Torr to 5 Torr, from 2 Torr to 5 Torr, from 3 Torr to 5 Torr or from 4 Torr to 5 Torr.

In some embodiments, the etching treatment 240 comprises an etch plasma. In some embodiments, the etch plasma is a conductively-coupled plasma (CCP) or inductively coupled plasma (ICP). In some embodiments, the etch plasma is a direct plasma or a remote plasma. In some embodiments, the etch plasma is operated at a power in a range of from 0 W to 500 W, from 50 W to 500 W, from 50 W to 400 W, from 50 W to 300 W, from 50 W to 200 W, from 50 W to 100 W, from 100 W to 500 W, from 100 W to 400 W, from 100 W to 300 W, from 100 W to 200 W, from 200 W to 500 W, from 200 W to 400 W or from 200 W to 300 W. In some embodiments, the minimum power for the plasma is greater than 0 W.

In some embodiments, the etch process occurs at a continuous power level. In some embodiments, the etch process occurs with second HFRF plasma pulses. In some embodiments, the each of the plurality of second HFRF plasma pulses are independently generated at an etch power is in a range of from 0 W to 500 W, from 50W to 500 W, from 50 W to 400 W, from 50 W to 300 W, from 50 W to 200 W, from 50 W to 100 W, from 100 W to 500 W, from 100 W to 400 W, from 100 W to 300 W, from 100W to 200 W, from 200 W to 500 W, from 200 W to 400 W or from 200 W to 300 W. In some embodiments, the minimum second plasma power is greater than 0 W. In some embodiments, the power of the pulses are the same during the etching treatment. In some embodiments, the power of the pulses varies during the etching treatment.

In one or more embodiments, the plurality of second HFRF plasma pulses have a duty cycle in arrange of from 1% to 50%, from 1% to 45%, from 1% to 40%, from 1% to 35%, from 1% to 30%, from 1% to 25%, from 1% to 20%, form 1% to 15%, from 1% to 10%, from 5% to 50%, from 5% to 45%, from 5% to 40%, from 5% to 35%, from 5% to 30%, from 5% to 25%, from 5% to 20%, form 5% to 15%, from 5% to 10%, from 10% to 50%, from 10% to 45%, from 10% to 40%, from 10% to 35%, from 10% to 30%, from 10% to 25%, from 10% to 20% or form 10% to 15%. In some embodiments, the duty cycles of the pulses are the same during the etching treatment. In some embodiments, the duty cycle of the pulses varies during the etching treatment.

In one or more embodiments, the each of the plurality of second HFRF plasma pulse has a pulse width in a range of from 5 msec to 50 μsec, from 4 msec to 50 μsec, from 3 msec to 50 μsec, from 2 msec to 50 μsec, from 1 msec to 50 μsec, from 800 μsec to 50 μsec, from 500 μsec to 50 μsec, from 200 μsec to 50 μsec, from 5 msec to 100 μsec, from 4 msec to 100 μsec, from 3 msec to 100 μsec, from 2 msec to 100 μsec, from 1 msec to 100 μsec, from 800 μsec to 100 μsec, from 500 μsec to 100 μsec and from 200 μsec to 100 μsec. In some embodiments, the pulse width of the pulses are the same during the etching treatment. In some embodiments, the pulse width of the pulses varies during the etching treatment.

In one or more embodiments, the each of the plurality of second HFRF plasma pulses independently has a pulse frequency in a range of from 0.1 kHz to 20 kHz, from 0.1 kHz to 15 kHz, from 0.1 kHz to 10 kHz, from 0.1 kHz to 5 kHz, 0.5 kHz to 20 KHz, from 0.5 kHz to 15 kHz, from 0.5 kHz to 10 kHz, from 0.5 kHz to 5 kHz, 1 kHz to 20 KHz, from 1 kHz to 15 kHz, from 1 kHz to 10 KHz, from 1 kHz to 5 kHz, 2 kHz to 20 KHz, from 2 kHz to 15 kHz, from 2 kHz to 10 KHz or from 2 kHz to 5 kHz. In some embodiments, the frequencies of the pulses are the same during the etching treatment. In some embodiments, the frequency of the pulses varies during the etching treatment.

In one or more embodiments, the plurality of second HFRF pulses have an etch radio frequency in a range of from 5 MHz to 20 MHZ, from 5 MHz to 15 MHZ, from 5 MHz to 10 MHz, from 10 MHz to 20 MHz or from 10 MHz to 15 MHz. In one or more embodiments, the plurality of second HFRF pulses have the second radio frequency of 13.56 MHz. In some embodiments, the radio frequencies of the pulses are the same during the etching treatment. In some embodiments, the radio frequency of the pulses varies during the etching treatment. In one or more embodiments, the each of the plurality of second HFRF pulses independently has an etch radio frequency in a range of from 5 MHz to 20 MHz, from 5 MHz to 15 MHz, from 5 MHz to 10 MHz, from 10 MHz to 20 MHz or from 10 MHz to 15 MHz. In one or more embodiments, the each of the plurality of second HFRF pulses independently has the second radio frequency of 13.56 MHz.

In one or more embodiments, the method 200 further comprises repeating the deposition process 220 and the etching film 240 for gap filling. In some embodiments, each of the repeating deposition process 220 and the repeating etching film 240 comprises an HFRF plasma. In some embodiments, the gap filling is seam-free. FIG. 3D illustrates the feature 110 that has been filled after multiple cycles through the deposition-etch-treat process.

In one or more embodiments, one or more additional effects further differentiate the etch rate of the non-conformal film on the sidewalls of the features than the non-conformal film on the bottom of the feature. In some embodiments, the one or more additional effects include nucleation rate of materials (e.g., Si) to be deposited on the substrate surface, properties of the substrate surface affecting the nucleation rate of materials to be deposited on the substrate surface, or the etch rate of materials (e.g., Si) to be deposited on the substrate surface.

Some embodiments include an optional post-processing 260 process. The post-process 260 can be used to modify the film 370 to improve some parameter of the film. In some embodiments, the post-process 260 comprises annealing the film 370. In some embodiments, post-process 260 can be performed by in-situ anneal in the same process chamber used for deposition 220 and/or etch 240. Suitable annealing processes include, but are not limited to, rapid thermal processing (RTP) or rapid thermal anneal (RTA), spike anneal, or UV cure, or e-beam cure and/or laser anneal. The anneal temperature can be in the range of about 500° C. to 900° C. The composition of the environment during anneal may include one or more of H₂, Ar, He, N₂, NH₃, SiH₄, etc. The pressure during the anneal can be in the range of about 100 mTorr to about 1 atm.

Some embodiments of the disclosure are directed to the deposition of conformal PECVD liners of metal doped carbon films using pulsed HFRF plasma processes. As used in this manner, “metal doped carbon” and “metal carbide” are used interchangeably to refer to a film that has metal and carbon atoms.

Some embodiments of the disclosure are directed to metal carbide (e.g., tungsten carbide) liners for dynamic random access memory (DRAM) devices. Some embodiments of the disclosure are directed to metal carbide liners memory or logic applications. Some embodiments of the disclosure are directed to methods for forming metal carbide hardmasks.

Conventional plasma-enhanced chemical vapor deposition of tungsten carbide forms “mushroom-shaped” films on top of narrow trenches and a very thin film at the sidewall resulting in poor conformal liners. Without being bound by any particular theory of operation, it is believed that plasma cannot penetrate sufficiently into the deep trenches resulting in the poor conformality. The current state-of-the-art for tungsten carbide deposition is by PECVD using a continuous HFRF plasma but does not result in good conformality, with the thinnest/thickest film conformality of about 22% for trenches with critical dimensions (CD) about 100 nm. The inventors have surprisingly found that tungsten carbide conformality can be improved to 40% to 70% or higher using the pulsed HFRF. In some embodiments, a pulsed HFRF plasma increases the conformality by 2× or greater.

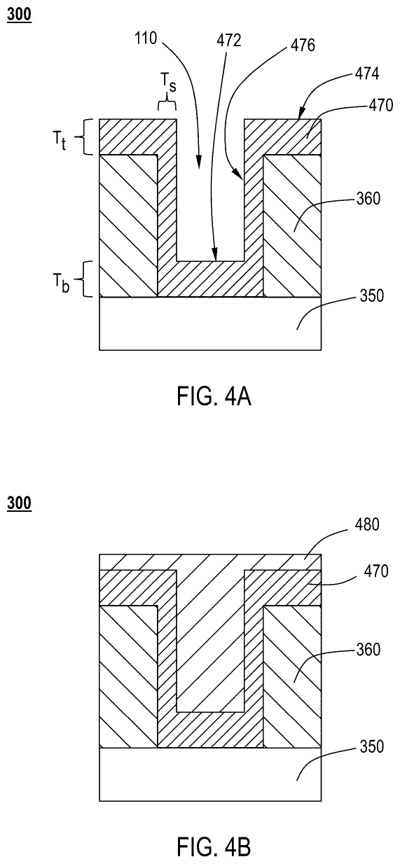

FIG. 4A illustrates another embodiment of the disclosure in which a metal carbide liner is formed using a pulsed HFRF plasma. The metal carbide liner of some embodiments is formed during liner formation process 215 as part of method 200. In some embodiments, the metal carbide liner is formed as part of a different method than that illustrated in method 200.

In the illustrated embodiments, the electronic device 300 has a metal carbide film 470 formed on the substrate surface, sidewalls and bottom of the feature 110. The film 470 deposited on the substrate will have a film thickness Tₛ at the sidewall of the feature, a film thickness Tₜ at the top of the feature (i.e., on the surface of the substrate) and a film thickness T_{b} at the bottom of the feature 110. The metal carbide film 470 has a bottom surface 472 at the bottom of the feature 110, a sidewall surface 476 at the sidewall of the feature 110 and a top surface 474 on the top surface of the feature 110.

In some embodiments, the film 470 forms conformally on the at least one feature. As used herein, the term “conformal”, or “conformally”, refers to a metal carbide layer that adheres to and uniformly covers exposed surfaces where the thickness of the film on the sidewalls is greater than or equal to 40% of the thickness of the film on the top/bottom of the feature. In some embodiments, the metal carbide film has a conformality in the range of 40% to 75%. In some embodiments, the metal carbide film has a conformality greater than or equal to 40%, 45%, 50%, 55%, 60%, 65% or 70%. The film 470 has greater conformality than films formed without a pulsed plasma (i.e., a continuous plasma), which typically has a conformality less than or equal to 25%.

In some embodiments, the film 470 is deposited to the average thickness in the range of from 1 nm to 100 nm, from 1 nm to 80 nm, from 1 nm to 50 nm, from 10 nm to 100 nm, from 10 nm to 80 nm, from 10 nm to 50 nm, from 20 nm to 100 nm, from 20 nm to 80 nm or from 20 nm to 50 nm before stopping deposition. In some embodiments, the film 470 is deposited to the average thickness in the range of from 5 nm to 100 nm, from 5 nm to 80 nm, from 5 nm to 40 nm, from 5 nm to 30 nm or from 10 nm to 30 nm.

The process parameters used for depositing the film 470 can affect the film thickness at the sidewall of the feature, top of the feature and/or bottom of the feature. For example, the particular precursors and/or reactive species, plasma conditions, temperature, etc. In some embodiments, the thickness Tₜ at the top of the feature is greater than the thickness Tₛ at the sidewall of the feature. In some embodiments, the thickness T_{b} at the bottom of the feature is greater than the thickness Tₛ at the sidewall of the feature. In some embodiments, the thickness Tₜ at the top of the feature is greater than the thickness T_{b} at the bottom of the feature. In some embodiments, the thickness T_{b} at the bottom of the feature is greater than the thickness Tₜ at the top of the feature.

During the film deposition process, the substrate is exposed to one or more process gases and/or conditions that form the film 470. In some embodiments, the process gas flows into a processing region of a process chamber and a pulsed HFRF plasma is formed from the process gas to deposit the film 470. The process gas of some embodiments includes a metal precursor and a carrier gas, and the carrier gas is ignited into a plasma by HFRF power. In some embodiments, the metal precursor comprises or consists essentially of a metal halide. As used in this manner, the term “consists essentially of” means that the active species of the metal precursor is greater than or equal to 95%, 98%, 99% or 99.5% of the stated species. In some embodiments, the metal halide comprises or consists essentially of fluorine atoms. In some embodiments, the metal halide comprises or consists essentially of chlorine atoms.

In some embodiments, the metal precursor comprises one or more of tungsten (W), molybdenum (Mo) or nickel (Ni). In some embodiments, the metal precursor comprises or consists essentially of tungsten hexafluoride (WF₆). In some embodiments, the metal precursor comprises or consists essentially of molybdenum (V) fluoride (MoF₅). In some embodiments, the metal precursor comprises or consists essentially of nickel (II) fluoride (NiF₂). In some embodiments, the metal precursor comprises or consists essentially of one or more of tungsten hexafluoride, molybdenum pentafluoride or nickel difluoride.

In one or more embodiments, the liner pulsed HFRF plasma is a conductively-coupled plasma (CCP) or inductively coupled plasma (ICP). In some embodiments, the liner pulsed HFRF plasma is a direct plasma or a remote plasma. In some embodiments, each of the plurality of liner HFRF pulses are independently generated at a liner power in a range of from 500 W to 1500 W, or in the range of 600 W to 1400 W, or in the range of 700 W to 1300 W, or in the range of 800 W to 1200 W. In some embodiments, the minimum liner plasma power is greater than 500 W. In some embodiments, all of the liner pulses have the same power. In some embodiments, the individual pulse powers in the liner HFRF plasma vary

In one or more embodiments, the plurality of liner HFRF plasma pulses have a liner duty cycle up to and including 99%. In some embodiments, the plurality of liner HFRF plasma pulses have a liner duty cycle in the range of 1% to 95%, from 1% to 90%, from 1% to 85%, from 1% to 80%, from 1% to 75%, from 1% to 70%, from 1% to 65%, from 1% to 60%, from 1% to 55%, from 5% to 95%, from 5% to 90%, from 5% to 85%, from 5% to 80%, from 5% to 75%, from 5% to 70%, from 5% to 65%, from 5% to 60%, from 5% to 55%, from 10% to 95%, from 10% to 45%, from 10% to 40%, from 10% to 35%, from 10% to 30%, from 10% to 25%, from 10% to 20% or form 10% to 15%. In some embodiments, each of the plasma pulses during the liner deposition process have the same duty cycle. In some embodiments, the duty cycle changes during the liner deposition process.

In one or more embodiments, each of the plurality of liner HFRF plasma pulse independently has a pulse width in a range of from 5 msec to 50 μsec, from 4 msec to 50 μsec, from 3 msec to 50 μsec, from 2 msec to 50 μsec, from 1 msec to 50 μsec, from 800 μsec to 50 μsec, from 500 μsec to 50 μsec, from 200 μsec to 50 μsec, from 5 msec to 100 μsec, from 4 msec to 100 μsec, from 3 msec to 100 μsec, from 2 msec to 100 μsec, from 1 msec to 100 μsec, from 800 μsec to 100 μsec, from 500 μsec to 100 μsec and from 200 μsec to 100 μsec. In some embodiments, each of the pulse widths are the same during the deposition process. In some embodiments, the pulse widths vary during the deposition process.

In one or more embodiments, each of the plurality of liner HFRF plasma pulses independently has a liner pulse frequency in a range of from 0.1 kHz to 20 KHz, from 0.1 KHz to 15 kHz, from 0.1 kHz to 10 KHz, from 0.1 kHz to 5 kHz, 0.5 kHz to 20 kHz, from 0.5 kHz to 15 kHz, from 0.5 kHz to 10 KHz, from 0.5 kHz to 5 kHz, 1 kHz to 20 kHz, from 1 kHz to 15 kHz, from 1 kHz to 10 KHz, from 1 kHz to 8 kHz, from 1 kHz to 5 kHz, 2 kHz to 20 KHz, from 2 kHz to 15 kHz, from 2 kHz to 10 KHz or from 2 kHz to 5 KHz. In some embodiments, the pulse frequency remains the same during the deposition process. In some embodiments, the pulse frequency varies during the deposition process.

The liner formation process 215 occurs before deposition process 220 as part of method 200 and can occur at any suitable substrate temperature. The substrate temperature during the liner formation process 215 can be the same as or different from the substrate temperature during the deposition process 220 or the etching 240.

In some embodiments, during the liner formation process 215, the substrate is maintained at a liner temperature in the range of 200° C. to 550° C., from 250° C. to 525° C., from 300° C. to 500° C., from 325° C. to 475° C., or from 350° C. to 450° C.

In some embodiments, the liner formation process 215 comprises a plasma enhanced chemical vapor deposition (CVD) process. In one or more embodiments, the liner formation process 215 comprises flowing one or more of a carrier gas, a liner precursor or a liner reactant onto the substrate surface. In some embodiments, the carrier gas includes but is not limited to argon (Ar), helium He, H₂ or N₂.

In one or more embodiments, each of the liner carrier gas, the liner precursor gas or the liner reactant gas are flown onto the substrate surface independently at a dose in a range of from 10 sccm to 500 sccm, from 15 sccm to 350 sccm, from 20 sccm to 200 sccm, from 25 sccm to 150 sccm, or from 50 sccm to 125 sccm.

In some embodiments, the liner formation process 215 results in a metal carbide film 470 having tensile stress. In some embodiments, the tensile stress of the metal carbide film 470 is greater than or equal to 1 GPa, 1.25 GPa, 1.5 GPa, 1.75 GPa or 2.0 GPa. The inventors have surprisingly found that a metal carbide film 470 formed using a pulsed HFRF plasma creates a file with tensile stress, whereas a typical metal carbide film formed by a different process has a stress that ranges from a low tensile stress (e.g., <1 GPa) to a compressive stress (e.g., a negative GPa).

After the liner formation process 215, the method 200 of some embodiments moves into the cycle of film deposition 220 followed by decision point 230 and optionally etching treatment 240 to form a seam-free gapfill. As shown in FIG. 4B, in some embodiments, whether according to method 200 or by a different method, a gapfill film 480 is formed in the feature 110 on the metal carbide liner 470.

In some embodiments, the metal carbide liner 470 is removed from the top surface of the substrate, leaving the metal carbide liner 470 on the sidewalls of the feature 110. In some embodiments, the metal carbide liner 470 is removed from the top surface of the substrate and the bottom surface of the feature 110 leaving the metal carbide liner substantially only on the sidewalls of the feature.

According to one or more embodiments, the substrate 100 is subjected to processing prior to and/or after forming the layer. This processing can be performed in the same chamber or in one or more separate processing chambers. In some embodiments, the substrate 100 is moved from the first chamber to a separate, second chamber for further processing. The substrate 100 can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition 220 and/or etching 240. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. The embodiments described herein may also be carried out using other suitable systems. The other suitable system includes but not limited to Producer®, Producer® XP Precision or their equivalents. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate 100 is continuously under vacuum or “load lock” conditions, and is not exposed to ambient air when being moved from one chamber to the next. The transfer chambers are thus under vacuum are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate 100 can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of gap filling, the method comprising:
exposing a substrate having a substrate surface to a deposition process comprising a pulsed high-frequency radio-frequency (HFRF) plasma having a plurality of HFRF pulses to deposit a non-conformal film, the substrate surface having a plurality of features formed therein, each of the plurality of features extending a distance into the substrate from the substrate surface and having a bottom and at least one sidewall, the non-conformal film having a greater thickness on the bottom of the features than on the at least one sidewall; and
exposing the non-conformal film to an etching treatment to etch a greater thickness of the non-conformal film on the sidewalls of the features than a thickness from the bottom of the features.

2. The method of claim 1, wherein each of the plurality of HFRF pulses independently has a pulse frequency in a range of from 1 kHz to 10 KHz.

3. The method of claim 1, wherein each of the plurality of HFRF pulses are independently generated at a power in a range of from 100 W to 300 W.

4. The method of claim 1, wherein each of the plurality of HFRF pulses has a radio frequency in a range of from 5 MHz to 15 MHz.

5. The method of claim 1, wherein the plurality of HFRF pulses have a duty cycle in a range of from 1% to 20%.

6. The method of claim 1, wherein the each HFRF pulse has a pulse width in a range of 1 msec to 100 μsec.

7. The method of claim 1, wherein the deposition process comprises a plasma enhanced chemical vapor deposition (PECVD) process, the PECVD comprises flowing one or more of a first carrier gas, a precursor or a first reactant onto the substrate surface independently at a dose in a range of from 40 sccm to 10000 sccm.

8. The method of claim 6, wherein the first carrier gas comprises helium (He) or Argon (Ar), the precursor gas comprises silane (SiH₄) or disilane (Si₂H₆), or the first reactant gas comprises H₂.

9. The method of claim 1, wherein the etching treatment comprises exposing the substrate surface to one or more of a second carrier gas or a second reactant gas.

10. The method of claim 8, wherein each of the second carrier gas or the second reactant gas are flown onto the substrate independently at a flow rate in the range of 250 sccm to 10000 sccm.

11. The method of claim 8, wherein the second carrier gas comprises one or more of argon (Ar), helium (He) or nitrogen (N₂), and/or the second reactant gas comprises H₂.

12. The method of claim 1 further comprises repeating the deposition process and the etching treatment to fill the feature.

13. The method of claim 11, wherein the feature is filled with amorphous silicon (a-Si).

14. The method of claim 1, wherein the non-conformal film has a thickness, the thickness has a variation in the range of 25% to 75% relative to the average thickness of the non-conformal film.

15. The method of claim 1, wherein the substrate is maintained at a temperature in the range of 25° C. to 175° C.

16. The method of claim 1 is performed at a pressure in a range of from 2 Torr to 5 Torr.

17. A method of using HFRF to a gap fill comprising:
exposing a substrate having a substrate surface with a plurality of features formed therein, each feature extending a distance into the substrate from the substrate surface and having a bottom and at least one sidewall to a chemical vapor deposition with a plurality of first HFRF pulses at 2 Torr pressure to deposit a film; and
etching the film by treating the substrate with an etch plasma at a pressure in a range of from 2 Torr to 5 Torr.

18. The method of claim 17, wherein the plurality of first HFRF pulses have a first pulse frequency in a range of from 1 kHz to 10 kHz at a first radio frequency in a range of from 5 MHz to 15 MHz and a first duty cycle in a range of from 1% to 20% at a first power of 300 W with the each of first HFRF pulse having a first pulse width in a range of from 1 msec to 100 μsec.

19. The method of claim 18, wherein the etch plasma comprises a plurality of second HFRF pulses with a pulse frequency in a range of from 1 kHz to 10 KHz at a second radio frequency in a range of from 5 MHz to 15 MHz and a second duty cycle in a range of from 1% to 20% at a second power in a range of from 100 W to 300 W with the each of second HFRF pulse having a second pulse width in a range of from 1 msec to 100 μsec.

20. A method of a low temperature a gap fill comprising:
providing a substrate having a substrate surface with a plurality of features formed therein, each feature extending a distance from the substrate surface and having a bottom and at least one sidewall;
depositing a film in the at least one feature by a plasma enhance chemical vapor deposition (PECVD) with a plurality of first HFRF pulses at 2 Torr pressure, the plasma enhance chemical vapor deposition (PECVD) comprises flowing a precursor gas SiH₄ at a dose in a range of from 40 sccm to 100 sccm, a first carrier gas He at a dose in a range of from 500 sccm to 5000 sccm and a first reactant gas H₂ at a dose in a range of from 200 sccm to 500 sccm onto the substrate surface; and
etching the film treating the substrate with an etch plasma at a pressure in a range of from 2 Torr to 5 Torr, the etching comprises flowing a second reactant gas H2 at a dose in a range of from 250 sccm to 500 sccm and a second carrier gas Ar at a dose in a range of from 250 sccm to 500 sccm onto the substrate surface, and
wherein the plurality of first HFRF pulses have a first pulse frequency in a range of from 1 kHz to 10 KHz at a first radio frequency of 13.56 MHz and a first duty cycle in a range of from 1% to 20% at a first power of 300 W with the each of first HFRF pulse having a first pulse width in a range of from 1 msec to 100 μsec.
